(19) United States
(12) Patent Application Publication
(10) Pub. No.: US 2024/0204141 A1
(43) Pub. Date: Jun. 20, 2024

(54) LIGHT EMITTING DIODE AND LIGHT EMITTING DEVICE

(71) Applicant: Tianjin Sanan Optoelectronics Co., Ltd., Tianjin (CN)

(72) Inventors: Jiayu LIU, Tianjin (CN); Weifan KE, Tianjin (CN); Shengnan LIU, Tianjin (CN); Pengjie HU, Tianjin (CN); Qiaotian WU, Tianjin (CN); Yuren PENG, Tianjin (CN); Huanshao KUO, Tianjin (CN); Liping CHOU, Tianjin (CN)

(73) Assignee: Tianjin Sanan Optoelectronics Co., Ltd., Tianjin (CN)

(21) Appl. No.: 18/488,050

(22) Filed: Oct. 17, 2023

(30) Foreign Application Priority Data
Dec. 16, 2022 (CN) 202211627233.5

(51) Int. Cl. H01L 33/38; H01L 33/40

(52) U.S. Cl. CPC H01L 33/385; H01L 33/405

(57) ABSTRACT

The disclosure relates to the technical field of semiconductor manufacturing and particularly relates to a light emitting diode having an epitaxial structure including a first-type semiconductor layer, an active layer, and a second-type semiconductor layer. An upper surface and a sidewall of a first pad electrode are covered with a first metal covering layer. The first metal covering layer is provided with a bump at a bottom portion of the sidewall of the first pad electrode. The bump is located below the insulating layer. In this way, the metal covering layer is allowed to completely cover the pad electrode and protect the edge of the bottom portion of the pad electrode. After the insulating layer is detached herein, an active material in the pad electrode below the insulating layer is prevented from contacting the external environment, and the reliability of the light emitting diode is therefore improved.

### CROSS-REFERENCE TO RELATED APPLICATION

This application claims the priority benefit of China application serial no. 202211627233.5, filed on Dec. 16, 2022. The entirety of the above-mentioned patent application is hereby incorporated by reference herein and made a part of this specification.

### BACKGROUND

### Technical Field

The disclosure relates to the technical field of semiconductor manufacturing, and in particular, relates to a light emitting diode and a light emitting device.

### Description of Related Art

A light emitting diode (LED) is a semiconductor light emitting element and is made of semiconductors such as GaN, GaAs, GaP, GaAsP, AlGaInP, etc. most of the time. The core of a light emitting diode is a PN junction with light emitting properties. LED has the advantages of high luminous intensity, high efficiency, small size, and long service life, and is considered to be one of the most potential light sources at present.

In the processing technology of the currently-available light emitting diode structure, the insulating layer above the pad electrode needs to be removed to expose the top of the pad electrode. However, due to the height difference in the position of the extended electrode when the film is turned over, the insulating layer may be detached from the edge of the pad electrode (as shown in FIG. 1). This causes the active material (such as an AuGe layer and other materials that are sensitive to the influence of foreign substances) inside the pad electrode to react with the external environment, causing defects in the light emitting diode chip. The reliability of light emitting diode is thus lowered.

### SUMMARY

In order to solve the problem of the insulating layer being detached from the edge of the pad electrode, causing the active material inside the pad electrode to react with the external environment as mentioned in the BACKGROUND, the disclosure provides a light emitting diode including an epitaxial structure, a first electrode, and an insulating layer.

The epitaxial structure has a first surface and a second surface opposite to each other. The epitaxial structure sequentially includes a first-type semiconductor layer, an active layer, and a second-type semiconductor layer in a direction from the first surface to the second surface.

The first electrode is electrically connected to the first-type semiconductor layer and at least includes a first pad electrode and a first extended electrode.

The insulating layer is located above an exposed mesa of the first-type semiconductor layer and the second-type semiconductor layer. The insulating layer is provided with a first via penetrating through the insulating layer. The first pad electrode is disposed in the first via and is electrically connected to the first-type semiconductor layer. The insulating layer is further provided with a second via. The first extended electrode is disposed in the second via and is electrically connected to the first-type semiconductor layer.

An upper surface and a sidewall of the first pad electrode are covered with a first metal covering layer. The first metal covering layer is provided with a first bump at a bottom portion of the sidewall of the first pad electrode. The first bump is located below the insulating layer and contacts the first-type semiconductor layer. The first metal covering layer is made of inert conductive metal.

The disclosure further provides a light emitting device adopting the light emitting diode according to any one of the above.

In the light emitting diode provided by the disclosure, an upper surface and a sidewall of the first pad electrode are covered with a first metal covering layer. The first metal covering layer is provided with a bump at a bottom portion of the sidewall of the first pad electrode, and the bump is located below the insulating layer. This allows the metal covering layer to completely cover the pad electrode and protect an edge of the bottom portion of the pad electrode. After the insulating layer is detached herein, an active material in the pad electrode below the insulating layer is prevented from contacting the external environment and causing chip defects, and the reliability of the light emitting diode is therefore improved.

Additional features and advantages of the disclosure will be set forth in the following specification, and in part will be apparent from the specification or can be learned by practice of the disclosure.

### BRIEF DESCRIPTION OF THE DRAWINGS

To make the technical solutions provided in the embodiments of the disclosure or the prior art more clearly illustrated, several accompanying drawings required by the embodiments or the prior art for description are briefly introduced as follows. Obviously, the drawings in the following description are some embodiments of the disclosure, and for a person having ordinary skill in the art, other drawings can be obtained based on these drawings without any inventive effort.

FIG. 1 is a schematic structural diagram of a light emitting diode provided by the prior art.

FIG. 2 is a schematic structural diagram of a light emitting diode provided by an embodiment of the disclosure.

FIG. 3 is an enlarged view of a local region A in FIG. 2.

FIG. 4 is a schematic diagram of implementation of a vertical structure of a light emitting diode provided by an embodiment of the disclosure.

FIG. 5 is a schematic diagram of implementation of a flip-chip structure of a light emitting diode provided by an embodiment of the disclosure.

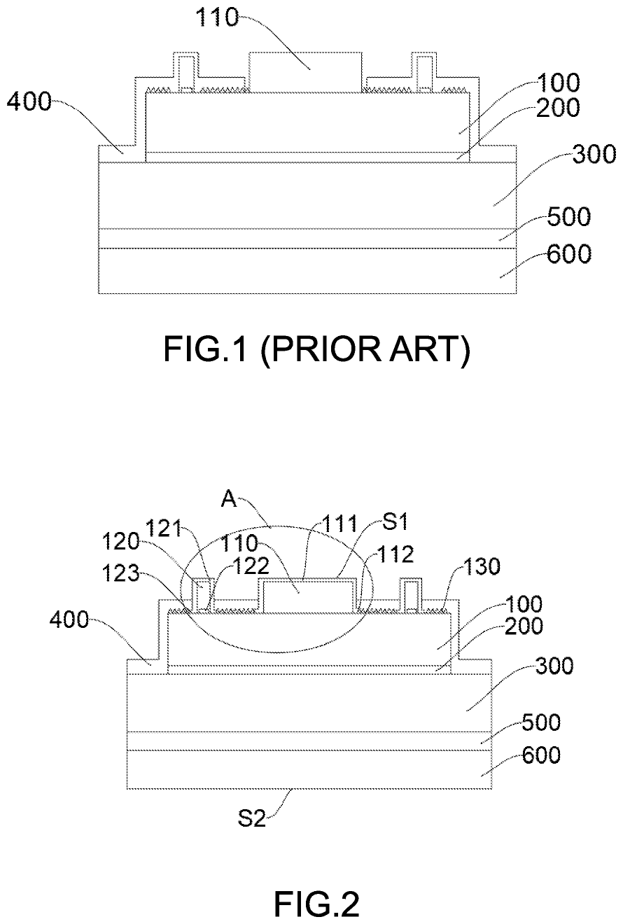

### DESCRIPTION OF THE EMBODIMENTS

In order to make the objectives, technical solutions, and advantages of the embodiments of the disclosure clearer, description will now be made in detail to clearly and completely present preferred embodiments of the disclosure, examples of which are illustrated in the accompanying drawings. Nevertheless, the disclosed embodiments are merely part of the embodiments of the disclosure, not all the embodiments. The technical features designed in the different embodiments of the disclosure described below can be combined with each other as long as the technical features do not conflict with each other. Based on the embodiments of the disclosure, all other embodiments obtained by a person having ordinary skill in the art without making any inventive effort fall within the scope that the disclosure seeks to protect.

### Embodiment 1

With reference to FIG. 2, FIG. 2 is a schematic structural diagram of a light emitting diode provided by the first embodiment of the disclosure. An epitaxial structure of the light emitting diode is formed on a growth substrate through physical vapor deposition (PVD), chemical vapor deposition (CVD), epitaxy growth technology, atomic layer deposition (ALD), and the like. The light emitting diode has a first surface S1 and a second surface S2 opposite to each other. The light emitting diode sequentially includes a first-type semiconductor layer 100, an active layer 200, and a second-type semiconductor layer 300 in a direction from the first surface S1 to the second surface S2.

Herein, the first-type semiconductor layer 100 and the second-type semiconductor layer 200 are semiconductors with different conductivity types, electrical properties, and polarities, and are doped with elements to provide electrons or holes. For instance, when the first-type semiconductor layer 100 is n-type, the second-type semiconductor layer 300 is p-type. The active layer 200 is formed between the first-type semiconductor layer 100 and the second-type semiconductor layer 300. Electrons and holes recombine in the active layer 200 driven by a current and convert electrical energy into light energy to emit light. The wavelength of light emitted by the light emitting diode is adjusted by changing a physical and chemical composition of one or more layers of the epitaxial light-emitting layer; and vice versa.

The active layer 200 provides a region of light radiation for electrons and holes to recombine. Different materials may be selected according to different emission wavelengths. A material of the active layer 200 is the aluminum gallium indium phosphide (AlGaInP) series, and the light it emits is red light, and the material may be a single heterostructure (SH), a double heterostructure (DH), a double-sided double heterostructure (DDH), or a multi-quantum well (MQW) structure. The active layer 200 includes a well layer and a barrier layer, where the barrier layer has a larger band gap than the well layer. By adjusting a composition ratio of the semiconductor materials in the active layer 200, it is expected to radiate light of different wavelengths. In this embodiment, it is preferred that the active layer 200 radiates light in the 550 nm to 950 nm band, such as red, yellow, orange, and infrared light. The active layer 200 is a material layer that provides electroluminescent radiation, such as aluminum gallium indium phosphorus or aluminum gallium arsenide, more preferably aluminum gallium indium phosphorus. Aluminum gallium indium phosphorus is a single quantum well or multiple quantum wells. In this embodiment, it is preferred that the semiconductor epitaxial stack radiates red light.

To be specific, as shown in FIG. 2, the light emitting diode further includes a first electrode. The first electrode at least includes a first pad electrode 110 and a first extended electrode 120. The first extended electrode 120 may be a single-layer, double-layer, or multi-layer structure, such as a stacked structure such as Ti/Al, Ti/Al/Ti/Au, Ti/Al/Ni/Au, V/Al/Pt/Au, AuGeNi, etc. In some embodiments, the first extended electrode 120 may be directly formed on a mesa of the epitaxial structure. After being deposited on the mesa, the first extended electrode 120 is fused at high temperature to form an alloy, thereby forming good ohmic contact with the first-type semiconductor layer 100. The first extended electrode 120 is electrically connected to the first-type semiconductor layer 100 through ohmic contact.

The light emitting diode further includes an insulating layer 400, and the insulating layer 400 may allow most of the light to pass through or allow most of the light to be reflected. A material of the insulating layer 400 includes a non-conductive material. The non-conductive material is preferably an inorganic material or a dielectric material, and the inorganic material may include silica gel. The dielectric material includes electrical insulating materials such as aluminum oxide, silicon nitride, silicon oxide, titanium oxide, or magnesium fluoride. For instance, the insulating layer 400 may be silicon dioxide, silicon nitride, titanium oxide, tantalum oxide, niobium oxide, barium titanate, or a combination thereof, and the combination thereof may be, for example, a Bragg reflector (DBR) formed by repeated stacking of two materials with different refractive indices.

To be specific, as shown in FIG. 2, the insulating layer 400 is located above an exposed mesa of the first-type semiconductor layer 100 and the second-type semiconductor layer 300. The insulating layer 400 is provided with a first via penetrating through the insulating layer, 400. The first pad electrode 110 is disposed in the first via and is electrically connected to the first-type semiconductor layer 100. The insulating layer 400 is further provided with a second via. The first extended electrode 120 is disposed in the second via and is electrically connected to the first-type semiconductor layer 100.

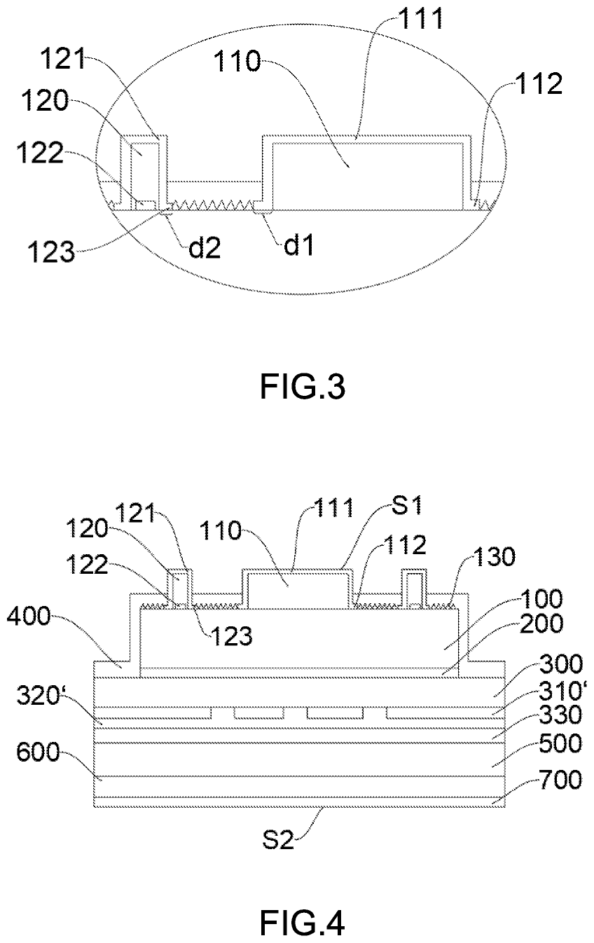

As shown in FIG. 2 and FIG. 3, an upper surface and a sidewall of the first pad electrode 110 are covered with a first metal covering layer 111. The first metal covering layer 111 is provided with a first bump 112 at a bottom portion of the sidewall of the first pad electrode 110. The first bump 112 is located below the insulating layer 400 and contacts the first-type semiconductor layer 100. The first metal covering layer 111 is made of inert conductive metal.

In the light emitting diode provided by the disclosure, the upper surface and the sidewall of the first pad electrode 110 are covered with the first metal covering layer 111. Further, the first metal covering layer 111 is provided with a bump at the bottom portion of the sidewall of the first pad electrode 110, and the bump is located below the insulating layer 400. This allows the metal covering layer to completely cover the pad electrode and protect an edge of the bottom portion of the pad electrode. Further, the first metal covering layer 111 is made of inert conductive metal, so that after the insulating layer 400 is detached herein, an active material in the pad electrode below the insulating layer 400 may be prevented from contacting the external environment and causing chip defects. The reliability of the light emitting diode is therefore improved.

In this embodiment, further, as shown in FIG. 2 and FIG. 3, an upper surface and a sidewall of the first extended electrode 120 are covered with a second metal covering layer 121. The second metal covering layer 121 is provided with a second bump 123 at a bottom portion of the sidewall of the first extended electrode 120. The second bump 123 is located below the insulating layer 400 and contacts the first-type semiconductor layer 100. The first metal covering layer 111 is made of inert conductive metal. To be specific, the number of the first extended electrode 120 may be one or more, such as 2, 3, 4, etc.

In some cases, a similar situation to the pad electrode may occur in the first extended electrode 120, and the insulating layer 400 may be detached from an edge of the first extended electrode 120. Therefore, the upper surface and the sidewall of the first extended electrode 120 are covered with the second metal covering layer 121. Further, the second metal covering layer 121 is provided with a bump at the bottom portion of the sidewall of the first extended electrode 120, and the bump is located below the insulating layer 400. This allows the metal covering layer to completely cover the first extended electrode 120 and protect the edge of the bottom portion of the first extended electrode 120. Further, the second metal covering layer 121 is made of inert conductive metal, so that after the insulating layer 400 is detached herein, the active material below the insulating layer 400 may be prevented from contacting the external environment and causing chip defects. The reliability of the light emitting diode is therefore improved.

Preferably, the first metal covering layer 111 and the second metal covering layer 121 may be made of inert conductive metal, which may be at least one of Au, Pt, or Ti, and Au is preferred as the metal covering layer herein.

Further, a thickness of each of the first metal covering layer 111 and the second metal covering layer 121 preferably is 10 Å to 1,000 Å. To be specific, this range of thickness is selected for each metal covering layer because if the thickness of each metal covering layer is excessively high, light may be reflected in the epitaxy. Most metal above 3000 Å forms reflection, so the thickness of each metal covering layer is preferably between 10 Å and 1000 Å, and more preferably between 50 Å and 800 Å.

Herein, as shown in FIG. 3, a distance d1 between the first bump 112 and a surface of the bottom portion of the sidewall of the first pad electrode 110 is 0.5 μm to 5 μm, and a thickness of the first bump 112 is 10 Å to 1,000 Å. The outward protruding distance of the bump is the distance range after the insulating layer 400 is detached, and the bump of this distance can ensure that the pad electrode is effectively protected.

In addition, preferably, as shown in FIG. 3, a distance d2 between the second bump 123 and a surface of the bottom portion of the sidewall of the first extended electrode 120 is 0.5 μm to 5 μm, and a thickness of the second bump 123 is less than 1,000 Å. Similarly, the outward protruding distance of the bump is the distance range after the insulating layer 400 is detached, and the bump of this distance can ensure that the pad electrode is effectively protected.

Based on the above embodiment, preferably, an ohmic contact layer 122 is disposed in the second via, and the extended electrode is electrically connected to the first-type semiconductor layer 100 through the ohmic contact layer 122. Generally, when a semiconductor contacts metal, a barrier layer is often formed. When the contact between the metal and the semiconductor has linear current-voltage characteristics or the contact resistance is negligible relative to the bulk resistance of the semiconductor, it is called ohmic contact.

Based on the above embodiment, preferably, as shown in FIG. 2, an upper surface of the first-type semiconductor layer 100 is provided with a roughened structure 130, and the roughened structure 130 may improve the light extraction efficiency of the light-emitting diode.

To be specific, a vertical light emitting diode is provided in this embodiment, and as shown in FIG. 4, the two electrodes of the vertically-structured light emitting diode chip are located on both sides of the epitaxial layer. This structure enables current to flow almost entirely vertically through the epitaxial layer of the light emitting diode. In this way, the current distribution problem of the planar structure may be improved, the light emitting efficiency may be improved, and the shading problem of the P electrode may also be solved, so the light emitting area of the LED is further increased.

A substrate 600 is disposed on an outer surface of the second-type semiconductor layer 300. The substrate 600 is a conductive substrate. After the second surface of the epitaxial structure of the light emitting diode element is bonded and transferred onto the substrate 600, an original epitaxial growth substrate of the epitaxial structure of the light emitting diode element is removed, so that the bonding between the substrate 600 and the epitaxial structure is completed. The substrate 600 is bonded onto the second surface of the epitaxial structure through a bonding layer 500, and the bonding layer 500 is a conductive bonding layer.

Preferably, GaP, SiC, Si, and GaAs with conductive properties may be used as the conductive substrate 600, and the bonding layer 500 is made of a metal conductive material.

More preferably, as shown in FIG. 4, a current-blocking layer 310′ is further disposed between the second-type semiconductor layer 300 and the bonding layer 500. Besides, an adhesion layer 320′ is disposed on one side of the current-blocking layer 310′, and the adhesion layer 320′ is a transparent oxide layer. Further, a mirror layer 330 is disposed between the bonding layer 500 and the current-blocking layer 310′, and preferably, a backside metallization layer 700 is disposed on an outer surface side of the substrate 600.

In addition to the structural features of the light emitting diode described above in this embodiment, a person having ordinary skill in the art, based on this embodiment, can add other structural features of the light emitting diode, such as an electrode, an ohmic contact layer, a current spreading layer, etc., to achieve corresponding purposes.

### Embodiment 2

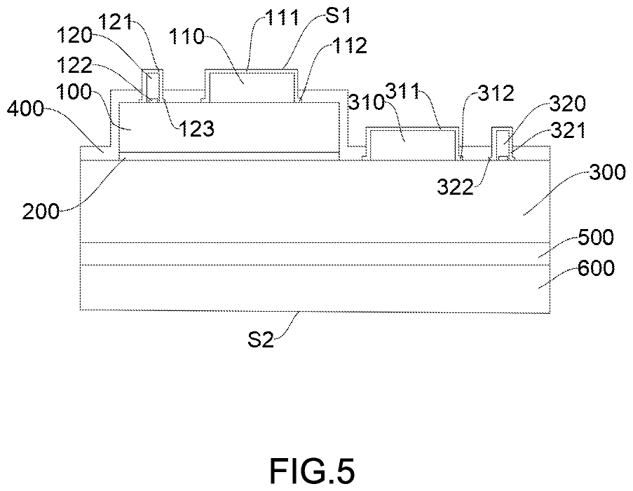

This embodiment provides a flip-chip light emitting diode. As specifically shown in FIG. 5, the flip-chip light emitting diode includes the substrate 600. In the embodiment of the manufacturing process of the light emitting diode, an epitaxial structure of the light emitting diode element is provided first. The light emitting diode sequentially includes the first-type semiconductor layer 100, the active layer 200, and the second-type semiconductor layer 300 in the direction from the first surface S1 to the second surface S2. The epitaxial structure includes a first surface and a second surface opposite to the first surface, and the first surface is closer to the first-type semiconductor layer 100 than the second surface. After the second surface of the epitaxial structure of the light emitting diode element is bonded and transferred onto the substrate 600, the original epitaxial growth substrate of the epitaxial structure of the light emitting diode element is removed, so that the bonding between the substrate 600 and the epitaxial structure is completed. The substrate 600 may be a conductive substrate or a non-conductive substrate or a transparent substrate or a non-transparent substrate. Preferably, the semiconductor epitaxial structure is bonded onto the substrate 600 through the bonding layer 500.

To be specific the light emitting diode further includes a second electrode electrically connected to the second-type semiconductor layer 300 and at least including a second pad electrode 310 and a second extended electrode 320. The insulating layer 140 is provided with a third via penetrating through the insulating layer 140. The second pad electrode 310 is disposed in the third via and is electrically connected to the second-type semiconductor layer 300. The insulating layer 400 is further provided with a fourth via. One end of the second extended electrode 320 is disposed in the fourth via and is electrically connected to the second-type semiconductor layer 300.

In this embodiment, preferably, an upper surface and a sidewall of the second pad electrode 310 are covered with a third metal covering layer 311. The third metal covering layer 311 is provided with a third bump 312 at a bottom portion of the sidewall of the second pad electrode 310. The third bump 312 is located below the insulating layer 400. The third metal covering layer 311 is made of inert conductive metal. In addition, preferably, an upper surface and a sidewall of the second extended electrode 320 are covered with a fourth metal covering layer 321. The fourth metal covering layer 321 is provided with a fourth bump 322 at a bottom portion of the sidewall of the second extended electrode 320. The fourth bump 322 is located below the insulating layer 140. The fourth metal covering layer 321 is made of inert conductive metal.

In some flip-chip light emitting diodes, at least 2 pad electrodes are included, or at least 2 extended electrodes are included. These pad electrodes and extended electrodes also face the phenomenon of the insulating layer 400 being detached from the edges. However, in this embodiment, as needed, the metal covering layer may be provided on the second pad electrode 310 or the second extended electrode 320 in the manner of Embodiment 1. Further, the metal covering layer is provided with a bump at the second pad electrode 310 or the bottom portion of the sidewall of the second extended electrode 320. The bump is located below the insulating layer 400, so that the metal covering layer is allowed to completely cover the pad electrode and protect the edge of the bottom portion of the pad electrode. The metal covering layer is made of inert conductive metal, so that after the insulating layer 400 is detached herein, the active material below the insulating layer may be prevented from contacting the external environment and causing chip defects.

Preferably, the same arrangement may also be employed if multiple pad electrodes or extended electrodes are provided.

Similarly, a material of each of the third metal covering layer 311 and the fourth metal covering layer 321 is at least one of Au, Pt, or Ti. A thickness of each of the third metal covering layer 311 and the fourth metal covering layer 321 may preferably be 10 Å to 1,000 Å.

In addition to the structural features of the light emitting diode described above in this embodiment, a person having ordinary skill in the art, based on this embodiment, can add other structural features of the light emitting diode, such as an electrode, an ohmic contact layer, a current spreading layer, etc., to achieve corresponding purposes.

### Embodiment 3

This embodiment provides a light emitting device. The light emitting device adopts the light emitting diode structure in any of the abovementioned embodiments or a preferred solution or a combination of the solutions in the embodiments. The light emitting device uses the red light or infrared light radiation provided by the light emitting diode to perform corresponding display or lighting or use of other optical devices.

In addition, a person having ordinary skill in the art shall understand that although there are many problems in the related art, each embodiment or technical solution of the disclosure can only be improved in one or several aspects, and it is not necessary to solve all the technical problems listed in the Related Art or the BACKGROUND section. It shall be understood by a person having ordinary skill in the art that anything that is not mentioned in a claim shall not be taken as a limitation on the claim.

Finally, it is worth noting that the foregoing embodiments are merely described to illustrate the technical means of the disclosure and should not be construed as limitations of the disclosure. Even though the foregoing embodiments are referenced to provide detailed description of the disclosure, people having ordinary skill in the art should understand that various modifications and variations can be made to the technical means in the disclosed embodiments, or equivalent replacements may be made for part or all of the technical features; nevertheless, it is intended that the modifications, variations, and replacements shall not make the nature of the technical means to depart from the scope of the technical means of the embodiments of the disclosure.

What is claimed is:

1. A light emitting diode, comprising:
an epitaxial structure having a first surface and a second surface opposite to each other, wherein the epitaxial structure sequentially comprises a first-type semiconductor layer, an active layer, and a second-type semiconductor layer in a direction from the first surface to the second surface,
a first electrode electrically connected to the first-type semiconductor layer and at least comprising a first pad electrode and a first extended electrode; and
an insulating layer located above an exposed mesa of the first-type semiconductor layer and the second-type semiconductor layer, wherein the insulating layer is provided with a first via penetrating through the insulating layer, the first pad electrode is disposed in the first via and is electrically connected to the first-type semiconductor layer, the insulating layer is further provided with a second via, and the first extended electrode is disposed in the second via and is electrically connected to the first-type semiconductor layer,
wherein an upper surface and a sidewall of the first pad electrode are covered with a first metal covering layer, the first metal covering layer is provided with a first bump at a bottom portion of the sidewall of the first pad electrode, the first bump is located below the insulating layer and contacts the first-type semiconductor layer, and the first metal covering layer is made of inert conductive metal.

2. The light emitting diode according claim 1, wherein an upper surface and a sidewall of the first extended electrode are covered with a second metal covering layer, the second metal covering layer is provided with a second bump at a bottom portion of the sidewall of the first extended electrode, the second bump is located below the insulating layer and contacts the first-type semiconductor layer, and the second metal covering layer is made of inert conductive metal.

3. The light emitting diode according claim 1, wherein a material of each of the first metal covering layer and a second metal covering layer is at least one of Au, Pt, or Ti.

4. The light emitting diode according claim 1, wherein a thickness of each of the first metal covering layer and a second metal covering layer is 10 Å to 1,000 Å.

5. The light emitting diode according claim 1, wherein a distance between the first bump and a surface of the bottom portion of the sidewall of the first pad electrode is 0.5 μm to 5 μm, and a thickness of the first bump is less than 1,000 Å.

6. The light emitting diode according claim 2, wherein a distance between the second bump and a surface of the bottom portion of the sidewall of the first extended electrode is 0.5 μm to 5 μm, and a thickness of the second bump is less than 1,000 Å.

7. The light emitting diode according claim 1, wherein an ohmic contact layer is disposed in the second via, and the first extended electrode is electrically connected to the first-type semiconductor layer through the ohmic contact layer.

8. The light emitting diode according claim 1, wherein an upper surface of the first-type semiconductor layer is provided with a roughened structure.

9. The light emitting diode according claim 1, wherein the light emitting diode has a vertical structure or a flip-chip structure.

10. The light emitting diode according claim 1, further comprising a second electrode electrically connected to the second-type semiconductor layer and at least comprising a second pad electrode and a second extended electrode,
wherein the insulating layer is provided with a third via penetrating through the insulating layer, the second pad electrode is disposed in the third via and is electrically connected to the second-type semiconductor layer, the insulating layer is further provided with a fourth via, and the second extended electrode is disposed in the fourth via and is electrically connected to the second-type semiconductor layer.

11. The light emitting diode according claim 10, wherein an upper surface and a sidewall of the second pad electrode are covered with a third metal covering layer, the third metal covering layer is provided with a third bump at a bottom portion of the sidewall of the second pad electrode, the third bump is located below the insulating layer, and the third metal covering layer is made of inert conductive metal.

12. The light emitting diode according claim 10, wherein an upper surface and a sidewall of the second extended electrode are covered with a fourth metal covering layer, the fourth metal covering layer is provided with a fourth bump at a bottom portion of the sidewall of the second extended electrode, the fourth bump is located below the insulating layer, and the fourth metal covering layer is made of inert conductive metal.

13. The light emitting diode according claim 11, wherein a material of each of the third metal covering layer and a fourth metal covering layer is at least one of Au, Pt, or Ti.

14. The light emitting diode according claim 11, wherein a thickness of each of the third metal covering layer and a fourth metal covering layer is 10 Å to 1,000 Å.

15. The light emitting diode according claim 1, wherein a bonding layer is disposed on a side of the second-type semiconductor layer away from the active layer, and a substrate is connected to the second-type semiconductor layer through the bonding layer.

16. The light emitting diode according claim 15, wherein a current-blocking layer is further disposed between the second-type semiconductor layer and the bonding layer.

17. The light emitting diode according claim 16, wherein an adhesion layer is disposed on one side of the current-blocking layer, and a mirror layer is disposed between the bonding layer and the current-blocking layer.

18. The light emitting diode according claim 15, wherein a backside metallization layer is disposed on an outer surface side of the substrate.

19. A light emitting device using the light emitting diode according to claim 1.
